(19) United States
(12) Patent Application Publication
(10) Pub. No.: US 2025/0246404 A1
(43) Pub. Date: Jul. 31, 2025

(54) PLASMA PROCESSING APPARATUS

(71) Applicant: Samsung Electronics Co., Ltd., Suwon-si (KR)

(72) Inventors: Euljin Park, Suwon-si (KR); Jinuk Park, Suwon-si (KR); Hongju Lee, Suwon-si (KR)

(21) Appl. No.: 19/021,310

(22) Filed: Jan. 15, 2025

(30) Foreign Application Priority Data
Jan. 30, 2024 (KR) 10-2024-0014354

(51) Int. Cl. H01J 37/32; H01L 21/67

(52) U.S. Cl. CPC H01J 37/32174; H01J 37/32642; H01L 21/67248; H01J 2237/002; H01J 2237/334

(57) ABSTRACT

A plasma processing apparatus includes a chamber, a lower electrode positioned inside the chamber and provided with a first radio frequency (RF) power, wherein a wafer is placed on an upper surface of the lower electrode, a radio frequency (RF)-induced electrode inside the chamber, an edge block impedance controller (EBIC) connected to the RF-induced electrode and configured to control an electric potential of the RF-induced electrode, wherein the EBIC is positioned outside the chamber, a cable connected to the EBIC and positioned outside the chamber, a lagging member surrounding the cable, and a cooler configured to cool down the cable.

### CROSS-REFERENCE TO RELATED APPLICATION

This application is based on and claims priority under 35 U.S.C. § 119 to Korean Patent Application No. 10-2024-0014354, filed on Jan. 30, 2024, in the Korean Intellectual Property Office, the disclosure of which is incorporated by reference herein in its entirety.

### BACKGROUND

The inventive concept relates to a plasma processing apparatus, and more particularly, to a plasma processing apparatus including an edge block impedance controller (EBIC).

Along with an increase in the number of stacking stages in next-generation semiconductor products, high aspect ratio etching is desirable, and particularly, the significance of skew-critical dimension (SCD) management indicating separation of upper and lower end centers of a profile tends to increase.

An EBIC technique is used as a method for controlling the etching rate of an edge region of a wafer in a next-generation ultra-high-difficult etching process. However, the EBIC technique causes a decrease in the etching rate of an edge region of a wafer and asymmetric etching according to a direction of the wafer. Accordingly, various resolutions to solve these problems have been discussed.

### SUMMARY

The inventive concept provides a plasma processing apparatus with improved reliability.

In addition, the problems to be solved by the technical idea of the inventive concept are not limited to the problem mentioned above, and other problems could be clearly understood by those of ordinary skill in the art from the description below.

According to aspects of the inventive concept, there are provided plasma processing apparatuses as follows.

According to an aspect of the present disclosure, a plasma processing apparatus includes a chamber, a lower electrode positioned inside the chamber and provided with a first radio frequency (RF) power, wherein a wafer is placed on an upper surface of the lower electrode, a radio frequency (RF)-induced electrode inside the chamber, an edge block impedance controller (EBIC) connected to the RF-induced electrode and configured to control an electric potential of the RF-induced electrode, wherein the EBIC is positioned outside the chamber, a cable connected to the EBIC and positioned outside the chamber, a lagging member surrounding the cable, and a cooler configured to cool down the cable.

According to an aspect of the present disclosure, a plasma processing apparatus includes a chamber configured to perform plasma etching on a wafer, an edge block impedance controller (EBIC) outside the chamber, a cable connected to the EBIC and positioned outside the chamber, a body having an inner space in which the cable is positioned, a first temperature sensor configured to measure a temperature of the cable in the inner space of the body, a cooler configured to cool down the cable, a fluid supply configured to store a fluid to be provided to the cooler, a fluid supply line connecting the cooler to the fluid supply, a valve configured to adjust a flow rate of the fluid passing through the fluid supply line, a controller configured to control opening and closing of the valve based on the temperature of the cable, which is measured by the first temperature sensor, a lower electrode positioned inside the chamber and provided with first power, and a radio frequency (RF)-induced electrode having a ring shape and connected to the EBIC. Second power that is lower than the first power is induced to the RF-induced electrode.

According to an aspect of the present disclosure, a plasma processing apparatus includes a chamber configured to perform plasma etching on a wafer, an edge block impedance controller (EBIC) outside the chamber, a cable connected to the EBIC and positioned outside the chamber, a body having an inner space in which the cable is positioned, a first temperature sensor configured to measure a temperature of the cable, a cooler configured to cool down the cable, a fluid supply configured to store a fluid to be provided to the cooler, a fluid supply line connecting the cooler to the fluid supply, a valve configured to adjust a flow rate of the fluid passing through the fluid supply line, a controller configured to control opening and closing of the valve based on the temperature of the cable, which is measured by the first temperature sensor, a lower electrode positioned inside the chamber and provided with first power, an insulating plate surrounding a side wall of the lower electrode, a focus ring on the insulating plate, a radio frequency (RF)-induced electrode having a ring shape and buried in the insulating plate, wherein second power that is lower than the first power is induced to the RF-induced electrode, an RF output rod, which is connected to the RF-induced electrode and outputs third power that is lower than the second power to the outside of the chamber, and an RF-induced rod connecting the RF-induced electrode to the RF output rod and penetrating the insulating plate. The controller is further configured to open the valve when the temperature of the cable, which is measured by the first temperature sensor, reaches or exceeds a first set temperature. The first set temperature is higher by about 10% to about 20% than an initial temperature of the cable.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a plasma processing apparatus according to embodiments;

FIG. 2 is a cross-sectional view schematically illustrating a chamber of FIG. 1;

FIG. 3 is a magnified view of a region R of FIG. 2;

FIG. 4 is a top view illustrating a radio frequency (RF)-induced electrode of a plasma processing apparatus according to embodiments;

FIG. 5 is a perspective view illustrating an RF-induced electrode of a plasma processing apparatus according to embodiments;

FIG. 6 is a schematic view illustrating a lagging member of a plasma processing apparatus according to embodiments;

FIG. 7 is a schematic view illustrating a lagging member according to embodiments;

FIG. 8 is a schematic view illustrating a cable arrangement member of FIG. 7; and

FIG. 9 is a schematic view illustrating a lagging member according to embodiments.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted.

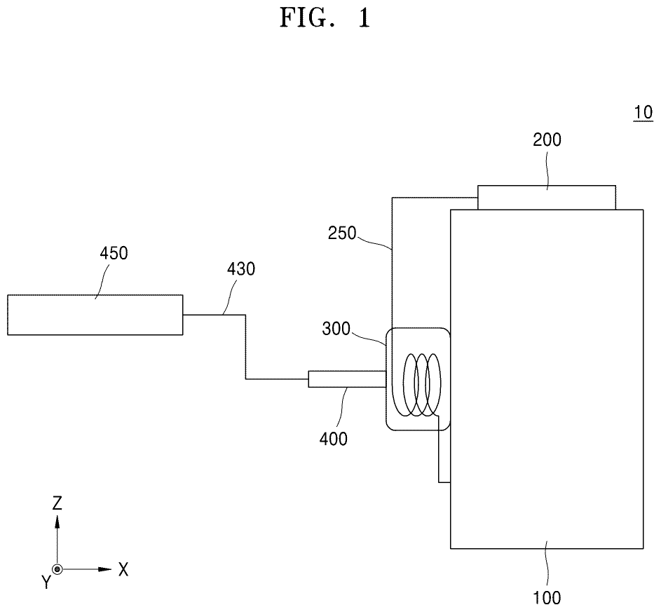

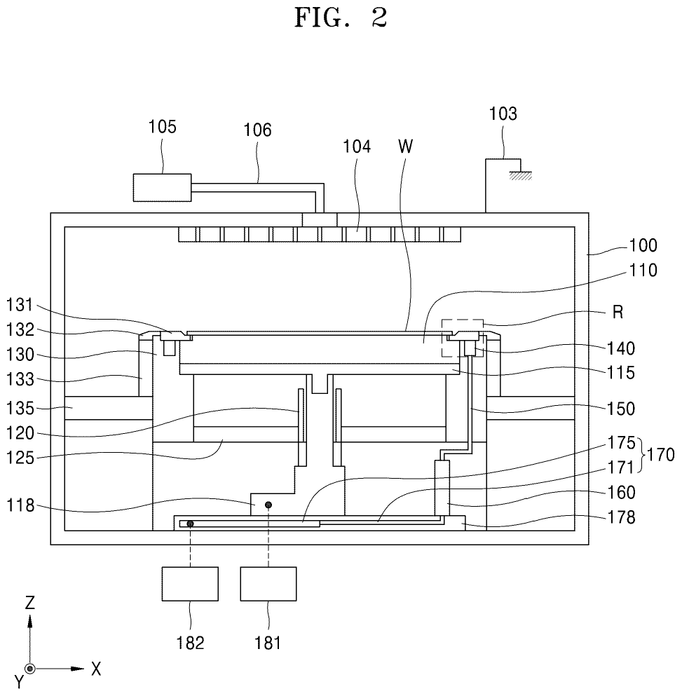

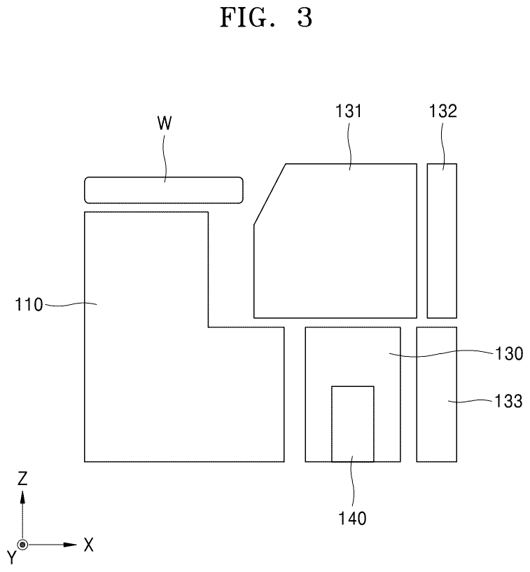

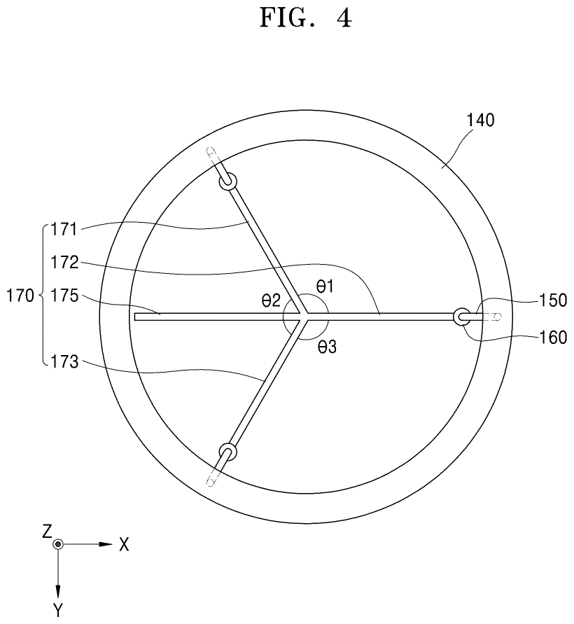

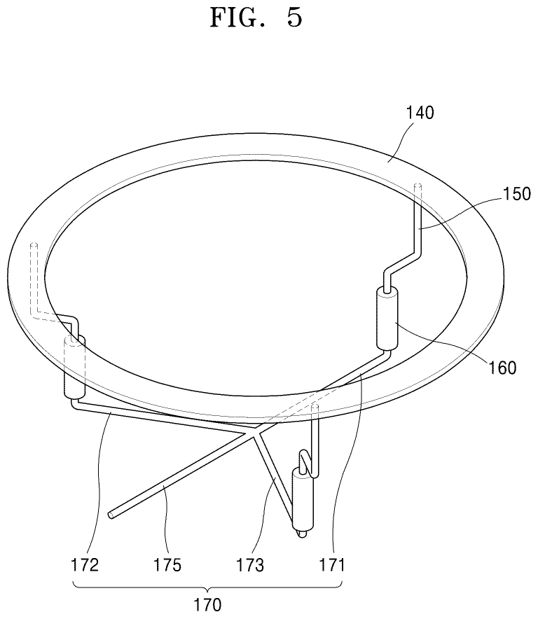

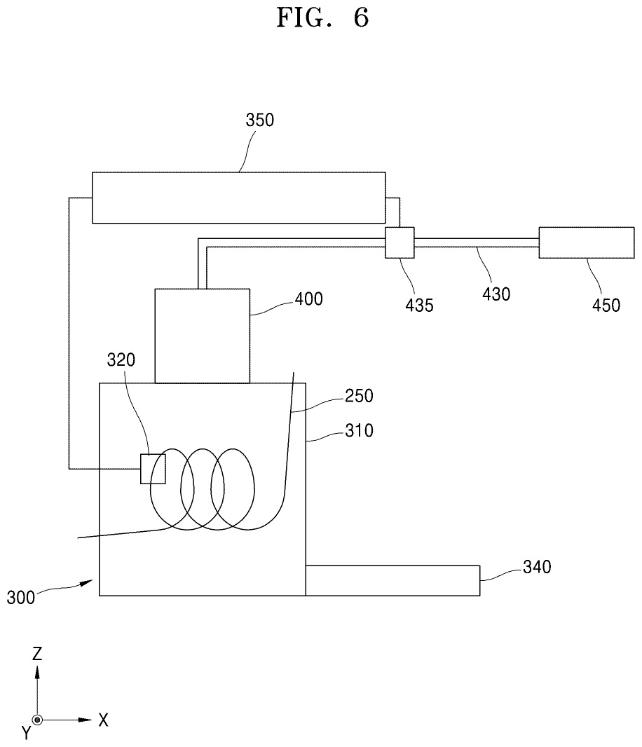

FIG. 1 is a cross-sectional view illustrating a plasma processing apparatus 10 according to embodiments. FIG. 2 is a cross-sectional view schematically illustrating a chamber 100 of FIG. 1. FIG. 3 is a magnified view of a region R of FIG. 2. FIG. 4 is a top view illustrating a radio frequency (RF)-induced electrode 140 of the plasma processing apparatus 10 according to embodiments. FIG. 5 is a perspective view illustrating the RF-induced electrode 140 of the plasma processing apparatus 10 according to embodiments. FIG. 6 is a schematic view illustrating a lagging member 300 of the plasma processing apparatus 10 according to embodiments.

Referring to FIGS. 1 to 6, the plasma processing apparatus 10 may include the chamber 100, an edge block impedance controller (EBIC) 200, a cable 250, the lagging member 300, a cooler 400, and a fluid supply 450.

The chamber 100 may act as a housing having therein a space in which a wafer W is to be processed. According to embodiments, the chamber 100 may have an isolated space to perform a plasma process on the wafer W. By isolating the chamber 100 from the outside, process conditions of a plasma process may be adjusted. For example, a temperature, pressure, and the like inside the chamber 100 may be adjusted to be different from a temperature, pressure, and the like outside the chamber 100.

In the drawings below, a direction perpendicular to an upper surface of a lower electrode 110 on which the wafer W is placed may be understood as the Z-axis direction, and the X-axis direction and the Y-axis direction may be understood to be parallel to the upper surface of the lower electrode 110. The X-axis direction may be perpendicular to the Y-axis direction. The Z-axis direction may be perpendicular to an X-Y plane. In addition, in the drawings below, a first horizontal direction, a second horizontal direction, and the vertical direction may be understood as follows. The first horizontal direction may be understood as the X-axis direction and represented by the first horizontal direction X, the second horizontal direction may be understood as the Y-axis direction and represented by the second horizontal direction Y, and the vertical direction may be understood as the Z-axis direction and represented by the vertical direction Z.

A gas feeder 104 may be on the ceiling of the chamber 100. The gas feeder 104 may be above the lower electrode 110. The gas feeder 104 may face the upper surface of the lower electrode 110 in the vertical direction Z. The gas feeder 104 may be grounded via a ground line 103. The gas feeder 104 may provide gas toward the upper surface of the wafer W seated on the upper surface of the lower electrode 110.

The gas feeder 104 may provide, to the inside of the chamber 100, gas to be used to generate plasma, by using a plurality of nozzles. In some embodiments, the plurality of nozzles may be arranged such that the gas is uniformly distributed. In some embodiments, the gas feeder 104 may include an upper electrode for a plasma process. In some embodiments, the gas feeder 104 may act as an upper electrode.

A plasma process may include dry-etching the upper surface of the wafer W by using plasma. In this case, the gas feeder 104 may provide, to the inside of the chamber 100, gas to be used in a plasma process. For example, the gas may be changed into plasma having radicals and ions for dry-etching.

A gas supply line 106 may be connected to the gas feeder 104. The gas supply line 106 may be connected to the ceiling of the chamber 100. The gas supply line 106 may be connected to a gas source 105 outside the chamber 100. The gas supply line 106 may provide gas to be used for plasma, which is provided from the gas source 105, to the inside of the chamber 100. Although FIG. 2 shows that the gas supply line 106 is above the ceiling of the chamber 100, the position of the gas supply line 106 is not limited thereto. The position of the gas supply line 106 may vary depending on the structure and position of the chamber 100 and the position of the gas source 105.

The gas source 105 may be configured to store gas to be used to generate plasma. The gas source 105 may supply the gas to the inside of the chamber 100 via the gas supply line 106 and the gas feeder 104. Although FIG. 2 shows that the gas source 105 provides the gas from the outside of the chamber 100 via the gas supply line 106, the technical idea of the inventive concept is not limited thereto. In some embodiments, the gas source 105 may be directly attached to the chamber 100.

The lower electrode 110 may be inside the chamber 100. The wafer W may be provided on the upper surface of the lower electrode 110. The lower electrode 110 may chuck the wafer W by using a voltage applied to the lower electrode 110. For example, an electrostatic force generated by the voltage may secure the wafer W in place.

A radio frequency (RF) plate 115 may be beneath the lower surface of the lower electrode 110. For example, a central portion of the RF plate 115 may protrude toward the bottom surface of the chamber 100. Although FIG. 2 shows that the width of the RF plate 115 in the first horizontal direction X is the same as the width of the lower electrode 110 in the first horizontal direction X, the technical idea of the inventive concept is not limited thereto. In some embodiments, the width of the RF plate 115 in the first horizontal direction X may be different from the width of the lower electrode 110 in the first horizontal direction X. The RF plate 115 may include a conductive material, e.g., aluminum (Al), but the technical idea of the inventive concept is not limited thereto.

An RF rod 118 may be beneath the RF plate 115. For example, the RF rod 118 may be connected to the protruding portion of the RF plate 115. The RF rod 118 may provide first power to the lower electrode 110 via the RF plate 115. The first power may be, for example, RF power including a first frequency and a second frequency that is lower than the first frequency.

A ground electrode 120 may surround the side wall of the RF rod 118. The ground electrode 120 may be separated from the side wall of the RF rod 118. In addition, the ground electrode 120 may be separated from the RF plate 115.

A ground plate 125 may be under the RF plate 115. The ground plate 125 may surround the side wall of the ground electrode 120. The ground plate 125 may be in contact with the ground electrode 120. Although not shown in FIG. 2, the ground plate 125 may be in contact with the outer wall of the chamber 100. The ground electrode 120 may be grounded to the outer wall of the chamber 100 via the ground plate 125.

An insulating plate 130 may surround each of the side wall of the lower electrode 110 and the side wall of the RF plate 115. The insulating plate 130 may be in contact with the ground plate 125. At least a portion of the insulating plate 130 may be in contact with the lower surface of the RF plate 115, but the technical idea of the inventive concept is not limited thereto. The insulating plate 130 may include an insulating material, e.g., ceramic. The term “contact,” as used herein, refers to a direct connection (i.e., physical touching) unless the context indicates otherwise.

A focus ring 131 may be on an edge of the upper surface of the lower electrode 110 and at least a portion of the upper surface of the insulating plate 130. The focus ring 131 may surround the side wall of a partial upper portion of the lower electrode 110. The focus ring 131 may have a ring shape. The focus ring 131 may include or may be formed of an insulating material.

An insulator ring 133 may surround the side wall of the insulating plate 130. The insulator ring 133 may be in contact with the side wall of the insulating plate 130. The insulator ring 133 may be separated from the focus ring 131. The insulator ring 133 may have a ring shape. The insulator ring 133 may include or may be formed of an insulating material.

An edge ring 132 may be on a portion of the upper surface of the insulating plate 130 and the upper surface of the insulator ring 133. The edge ring 132 may surround the side wall of the focus ring 131. The edge ring 132 may be in contact with each of the insulating plate 130, the insulator ring 133, and the focus ring 131. The edge ring 132 may have a ring shape. The edge ring 132 may include or may be formed of an insulating material.

A baffle unit 135 may be between the insulating plate 130 and the side wall of the chamber 100. However, the technical idea of the inventive concept is not limited thereto. In some embodiments, the baffle unit 135 may be between the insulator ring 133 and the side wall of the chamber 100.

The baffle unit 135 may be in contact with each of the side wall of the chamber 100 and the side wall of the insulating plate 130. However, the technical idea of the inventive concept is not limited thereto. In some embodiments, the baffle unit 135 may be separated from any one of the side wall of the chamber 100 and the side wall of the insulating plate 130.

The baffle unit 135 may have a ring shape. The baffle unit 135 may include a plurality of baffle holes penetrating the baffle unit 135 in the vertical direction Z. The plurality of baffle holes may be separated from each other. Process gas existing inside the chamber 100 may be exhausted through the plurality of baffle holes formed in the baffle unit 135.

The RF-induced electrode 140 may be inside the insulating plate 130. That is, the RF-induced electrode 140 may be buried inside the insulating plate 130. The RF-induced electrode 140 may be adjacent to the focus ring 131 which is disposed on the upper surface of the insulating plate 130. According to embodiments, the RF-induced electrode 140 acts as an electrode and may be formed as a metal electrode including metal. The RF-induced electrode 140 (i.e., an edge electrode) may control an electric field in an edge region of the wafer W and control etching asymmetry and uniformity of the edge region of the wafer W based on the electric field. The EBIC 200 may control the RF-induced electrode 140. In an embodiment, the edge electrode 140 may be electrically connected to the EBIC 200. The EBIC 200 may control a plasma sheath position and a distribution of directions of ions hitting the edge region of the wafer by adjusting an electric potential of the edge electrode 140, thereby achieving uniform plasma processing at the edge region of the wafer W. In an embodiment, the EBIC 200 may include a variable capacitor. Controlling an impedance of the variable capacitor included in the EBIC 200 may allow controlling a direction of an ion flux arriving at the edge region of the wafer W, and controlling the harmonics generated in the plasma sheath. In an embodiment, the harmonics controlled by the EBIC 200 may be harmonics above or equal to 100 MHz. This is because a plasma density concentration in the central region is greatly affected at frequencies above or equal to 100 MHz.

A portion of the first power provided from the lower electrode 110 may be provided to a space between the wafer W and the gas feeder 104 via the focus ring 131. In addition, the other portion of the first power provided from the lower electrode 110 may be induced to the RF-induced electrode 140 via the focus ring 131. RF power induced to the RF-induced electrode 140 may be second power that is lower than the first power. The second power may include, for example, the first frequency and the second frequency that is lower than the first frequency. A portion of the second power having the second frequency may be included in the harmonics and may be filtered out by the EBIC 200.

A portion of an RF-induced rod 150 may penetrate the insulating plate 130. The other portion of the RF-induced rod 150 may extend downward from the insulating plate 130. A plurality of RF-induced rods 150 may be included. For example, as shown in FIGS. 4 and 5, three RF-induced rods 150 may be connected to the RF-induced electrode 140. The RF-induced rod 150 may have, for example, a line shape. However, the technical idea of the inventive concept is not limited thereto.

The width of the RF-induced rod 150 in the first horizontal direction X may be less than the width of the RF-induced electrode 140 in the first horizontal direction X. The RF-induced rod 150 may be separated by a certain gap from the side wall of the lower electrode 110. The gap between the RF-induced electrode 140 and the side wall of the lower electrode 110 may be less than the gap between the RF-induced rod 150 and the side wall of the lower electrode 110. The RF-induced rod 150 may include or may be formed of a conductive material.

An RF filter 160 may be connected to one end of the RF-induced rod 150 inside the chamber 100. That is, the RF-induced rod 150 may connect the RF-induced electrode 140 to the RF filter 160. The number of RF filters 160 may correspond to the number of RF-induced rods 150. The RF filter 160 may have, for example, a coil shape.

The RF filter 160 may provide third power to an RF output rod 170, the third power being generated by removing RF power having the first frequency that is a relatively high frequency, from the second power provided from the RF-induced electrode 140 via the RF-induced rod 150. Particularly, the RF filter 160 may pass therethrough RF power having the second frequency and then provide same to the RF output rod 170, and block RF power having the first frequency that is higher than the second frequency. Accordingly, the third power provided to the RF output rod 170 may have RF power having the second frequency that is a relatively low frequency. The RF power having the first frequency may be used in a plasma process. By using the RF filter 160 to prevent the RF power having the first frequency, which is to be used in a plasma process, from being output to the outside of the chamber 100, the efficiency of the plasma process may be improved.

The RF output rod 170 may be connected to the RF filter 160. That is, the RF filter 160 may connect the RF-induced rod 150 to the RF output rod 170. The RF output rod 170 may be connected to the RF-induced electrode 140 via the RF filter 160 and the RF-induced rod 150. The RF output rod 170 may be inside an RF output plate 178 on the bottom surface of the chamber 100. However, the technical idea of the inventive concept is not limited thereto. The RF output plate 178 may include an insulating material.

The RF output rod 170 may include a plurality of RF connection lines and an RF output line 175. The plurality of RF connection lines may be provided in number corresponding to the number of RF-induced rods 150. The RF output rod 170 may include, for example, first to third RF connection lines 171, 172, and 173.

Each of the First to third RF connection lines 171, 172, and 173 may have a line shape. One ends of the first to third RF connection lines 171, 172, and 173 may be connected with each other. Each of the other ends of the first to third RF connection lines 171, 172, and 173 may be connected to a corresponding RF filter of the three RF filters 160.

The first to third RF connection lines 171, 172, and 173 may be separated at the same angle from each other on a plane defined by the first horizontal direction X and the second horizontal direction Y that is perpendicular to the first horizontal direction X. For example, as shown in FIG. 4, the first RF connection line 171 may be separated at a first angle θ1 from the second RF connection line 172. The second RF connection line 172 may be separated at a second angle θ2 from the third RF connection line 173. The third RF connection line 173 may be separated at a third angle θ3 from the first RF connection line 171. In some embodiments, the first to third angles θ1, θ2, and θ3 may have the same value of 120 degrees.

The RF output line 175 may be connected to a portion to which the first to third RF connection lines 171, 172, and 173 are connected. The RF output line 175 may have a line shape. For example, the RF output line 175 may be on the same plane as a plane on which the first to third RF connection lines 171, 172, and 173 are disposed. However, the technical idea of the inventive concept is not limited thereto. For example, the RF output line 175 may be between the second RF connection line 172 and the third RF connection line 173.

Each of the first to third RF connection lines 171, 172, and 173 and the RF output line 175 may include or may be formed of a conductive material. The third power provided via the RF filter 160 may be output to the outside of the chamber 100 via the first to third RF connection lines 171, 172, and 173 and the RF output line 175.

A first controller 181 may be connected to the RF rod 118. The first controller 181 may provide the first power to the RF rod 118. The first controller 181 may control the first power to be provided to the RF rod 118. In an embodiment, the first controller 181 may include an RF power source generating the first power (i.e., a first RF power).

A second controller 182 may be connected to the RF output rod 170. Particularly, the second controller 182 may be connected to the RF output line 175 of the RF output rod 170. The second controller 182 may be different from the first controller 181. That is, the second controller 182 may operate independently of the first controller 181. The second controller 182 may control the third power to be output to the outside of the chamber 100 via the RF output rod 170.

The lagging member 300 may be outside the chamber 100. According to embodiments, the lagging member 300 may be adjacent to the outer wall of the chamber 100. The lagging member 300 may include a body 310, a first temperature sensor 320, and a controller 350. The body 310 may have therein a space in which the cable 250 is arranged.

The cable 250 may connect the EBIC 200 to the RF-induced electrode 140. According to embodiments, the length of the cable 250 may be within a range of about 2.9 m to about 3.1 m. At least a portion of the cable 250 may be inside the body 310. According to embodiments, the body 310 may include or may be formed of a heat insulating material. According to embodiments, the body 310 may surround the cable 250. The cable 250 inside the body 310 may be sealed by the body 310. In some embodiments, the body 310 may include fabric. According to embodiments, the length of the body 310 in the first horizontal direction X may be within a range of about 36 cm to about 44 cm, the length of the body 310 in the second horizontal direction Y may be within a range of about 72 cm to about 88 cm, and the length of the body 310 in the vertical direction Z may be within a range of about 2.7 cm to about 3.3 cm.

The first temperature sensor 320 may be adjacent to the cable 250 inside the body 310. In some embodiments, the first temperature sensor 320 may contact the cable. The first temperature sensor 320 may measure the temperature of the cable 250. According to embodiments, the first temperature sensor 320 may include a thermocouple temperature sensor, a resistance temperature detector (RTD), an infrared temperature sensor, a thermistor, or the like. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The cooler 400 may cool down the cable 250 inside the body 310. According to embodiments, the cooler 400 may cool down the cable 250 by providing a refrigerant to the inside of the body 310. For example, the cooler 400 may cool down the cable 250 by providing gas, such as air and nitrogen (N₂), to the inside of the body 310. According to embodiments, the cooler 400 may include a powerless air cooler or a non-refrigerant air cooler. The cooler 400 may be outside the chamber 100. The cooler 400 may be adjacent to the lagging member 300. A fluid passing through the cooler 400 may have a temperature that is lower than a temperature before the fluid is provided to the cooler 400. That is, the fluid passing through the cooler 400 may be cooled down by the cooler 400. The powerless air cooler, also known as a non-electric air cooler or evaporative cooler, may operate without the need for electricity. Instead, it uses natural processes such as evaporation to cool the air.

The fluid supply 450 may store the fluid to be supplied to the cooler 400. The fluid stored in the fluid supply 450 may include a fluid to be used in a fabrication facility (FAB). The fluid supply 450 may supply the fluid to the cooler 400 through a fluid supply line 430. The fluid supply line 430 may be connected to each of the fluid supply 450 and the cooler 400.

A valve 435 may adjust the flow rate of the fluid passing through the fluid supply line 430. The valve 435 may include at least one of a stop valve, a gate valve, a check valve, a plug valve, a ball valve, a butterfly valve, and a diaphragm valve. An exhaust port 340 may be configured to discharge the fluid existing inside the body 310 to the outside of the body 310. For example, the exhaust port 340 may be a passage through which the fluid provided to the inside of the body 310 by the cooler 400 is discharged to the outside of the body 310.

The controller 350 may control the temperature of the cable 250. Particularly, the controller 350 may control the temperature of the cable 250 by adjusting the valve 435 based on the temperature of the cable 250, which is measured by the first temperature sensor 320. The controller 350 may control the valve 435 to adjust the flow rate of the fluid to be provided to the inside of the body 310 by the cooler 400. For example, if the temperature of the cable 250, which is measured by the first temperature sensor 320, is a set temperature T1 or higher, the controller 350 may control the valve 435 to be opened such that the fluid passes through the cooler 400. Otherwise, if the temperature of the cable 250, which is measured by the first temperature sensor 320, is lower than the set temperature T1, the controller 350 may control the valve 435 to be closed such that the fluid does not further pass through the cooler 400. Herein, the temperature of the fluid provided to the inside of the body 310 may be lower than the set temperature T1 by the cooler 400. According to embodiments, the temperature of the fluid provided to the inside of the body 310 after passing through the cooler 400 may be higher than 0 degree Celsius and lower than or equal to an initial temperature TO of the cable 250. According to embodiments, the set temperature T1 may be higher by about 10% to about 20% than the initial temperature TO of the cable 250. However, the set temperature T1 is not limited to the temperature range described above. In addition, in the specification, an object to be controlled by the controller 350 is not limited to the valve 435. The controller 350 may just control a component capable of cooling down the cable 250. For example, when the temperature of the cable 250 is adjusted by turning on or off the cooler 400, the controller 350 may control the cooler 400 to be turned on or off. In some embodiments, the controller 350 may control both the valve 435 and the cooler 400.

The controller 350 may be implemented by hardware, firmware, software, or a combination thereof. For example, the controller 350 may include a computing device, such as a workstation computer, a desktop computer, a laptop computer, and a tablet computer. The controller 350 may include a simple controller, a complicated processor, such as a microprocessor, a central processing unit (CPU), and a graphics processing unit (GPU), a processor composed of software, exclusive hardware, or firmware. The controller 350 may be implemented by, for example, a general-purpose computer or application-specific hardware, such as a digital signal processor (DSP), a field programmable gate array (FPGA), and an application specific integrated circuit (ASIC). The controller 350 may be implemented by instructions readable and executable by one or more processors and stored in machine-readable media. Herein, the machine-readable media may include an arbitrary mechanism configured to store and/or transmit information in the form readable by a machine (e.g., a computing device). For example, the machine-readable media may include read-only memory (ROM), random access memory (RAM), magnetic disc storage media, optical storage media, flash memory devices, electrical, optical, acoustic, or other form of radio wave signals (e.g., carrier waves, infrared signals, digital signals, and the like), and other arbitrary signals.

The plasma processing apparatus 10 according to the technical idea of the inventive concept may constantly maintain the temperature of the cable 250 connected to the EBIC 200. For example, while cooling down the cable 250 by the cooler 400, the cable 250 may be efficiently cooled down through the lagging member 300. In addition, when a powerless air cooler is used as the cooler 400, the cable 250 may be efficiently cooled down without using separate power. Furthermore, because gas used in a FAB may also be used as the fluid provided to the cooler 400, the cable 250 may be efficiently cooled down without a separate additional costs of installing a separate gas tank for cooling purpose only.

In addition, under control by the controller 350, the temperature of the cable 250 may be measured in real-time to constantly maintain the temperature of the cable 250 by using the cooler 400. By constantly maintaining the temperature of the cable 250 connected to the EBIC 200, the impedance value inside the chamber 100 may be constantly maintained, thereby eventually etching an edge portion of the wafer W uniformly. In addition, because the temperature of the cable 250 is constantly maintained, replacing and repairing the cable 250 may be unnecessary or avoided, thereby improving the yield of semiconductor chips.

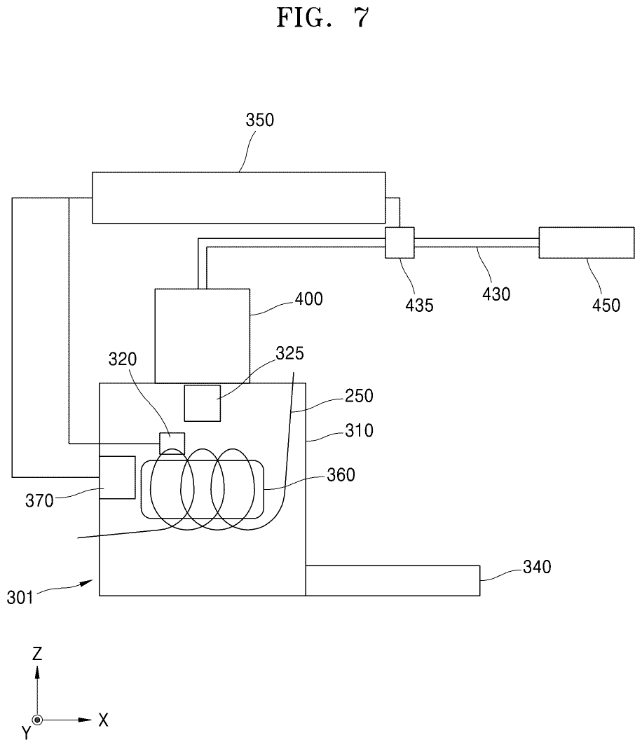

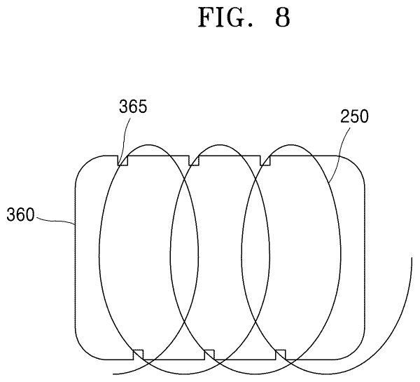

FIG. 7 illustrates a lagging member 301 according to embodiments. FIG. 8 illustrates a cable arrangement member 360 of FIG. 7. Hereinafter, the description made with reference to FIGS. 1 to 6 is omitted, and differences from the description made with reference to FIGS. 1 to 6 are mainly described.

Referring to FIGS. 7 and 8, the lagging member 301 may include the body 310, the first temperature sensor 320, a second temperature sensor 370, the cable arrangement member 360, a temperature display panel 325, the exhaust port 340, and the controller 350.

The body 310 may have therein a space in which the cable 250 is arranged. At least a portion of the cable 250 may be inside the body 310. The first temperature sensor 320 may be adjacent to the cable 250 inside the body 310. The first temperature sensor 320 may measure the temperature of the cable 250.

The second temperature sensor 370 may measure the internal temperature of the body 310 (i.e., an internal temperature of an inner space of the body). According to embodiments, the second temperature sensor 370 may include a thermocouple temperature sensor, an RTD, an infrared temperature sensor, a thermistor, or the like. For example, the first temperature sensor 320 may contact the cable 250 or may be positioned at a first distance from the cable 250, and the second temperature sensor 370 may be positioned at a second distance from the cable 250. The second distance is greater than the first distance.

The controller 350 may control the temperature of the cable 250 based on the temperatures measured by the first temperature sensor 320 and the second temperature sensor 370. According to embodiments, the controller 350 may control the temperature of the cable 250 by controlling opening and closing of the valve 435 based on the difference between the temperature measured by the first temperature sensor 320 and the temperature measured by the second temperature sensor 370. Because the controller 350 may control the temperature of the cable 250 based on the temperature measured by each of the first temperature sensor 320 and the second temperature sensor 370, the controller 350 may accurately control the temperature of the cable 250.

The cooler 400 may cool down the cable 250 inside the body 310. The fluid supply 450 may store the fluid to be supplied to the cooler 400. The fluid stored in the fluid supply 450 may include a fluid to be used in a FAB. The fluid supply 450 may supply the fluid to the cooler 400 through the fluid supply line 430. The fluid supply line 430 may be connected to each of the fluid supply 450 and the cooler 400. The valve 435 may adjust the flow rate of the fluid passing through the fluid supply line 430. The exhaust port 340 may be configured to discharge the fluid existing inside the body 310 to the outside of the body 310.

The cable arrangement member 360 may be provided inside the body 310. The cable arrangement member 360 may be configured to fix the cable 250 inside the body 310. According to embodiments, the cable arrangement member 360 may have grooves 365 formed in the surface thereof as shown in FIG. 8. The cable 250 may be fixed to the cable arrangement member 360 by the grooves 365 formed in the surface of the cable arrangement member 360. For example, the cable 250 may be secured in the grooves 365. However, the shape of the cable arrangement member 360 is not limited thereto. For example, the cable arrangement member 360 may have various shapes to fix the cable 250 thereto.

The temperature display panel 325 may be formed on the outer surface of the body 310. For example, the temperature display panel 325 may be formed on the outer surface of the body 310. The temperature display panel 325 may display at least any one of the temperatures measured by the first temperature sensor 320 and the second temperature sensor 370.

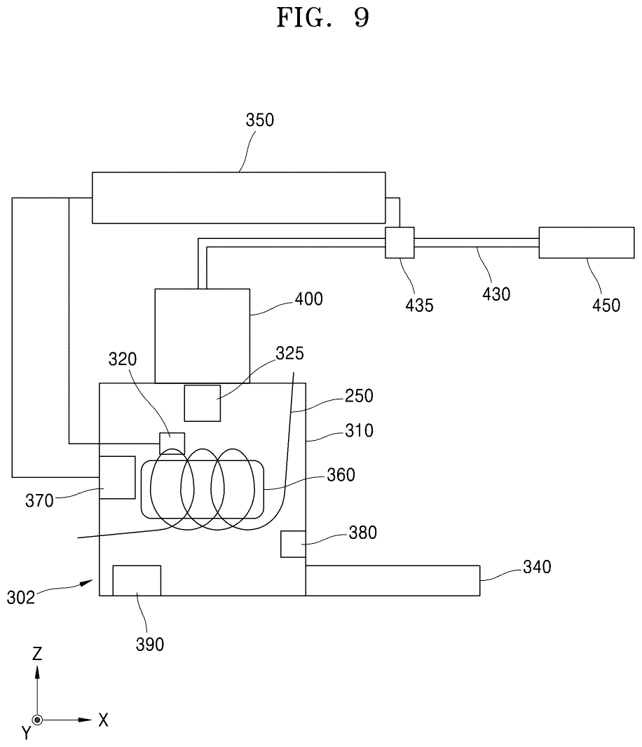

FIG. 9 is a schematic view illustrating a lagging member 302 according to embodiments. Hereinafter, the description made with reference to FIGS. 1 to 8 is omitted, and differences from the description made with reference to FIGS. 1 to 8 are mainly described.

Referring to FIG. 9, the lagging member 302 may include the body 310, the first temperature sensor 320, the second temperature sensor 370, the cable arrangement member 360, the temperature display panel 325, the exhaust port 340, an overheat detection sensor 380, a smoke detector 390, and the controller 350.

The body 310 may have therein a space in which the cable 250 is arranged. At least a portion of the cable 250 may be inside the body 310. The first temperature sensor 320 may be adjacent to the cable 250 inside the body 310. In some embodiments, the first temperature sensor 320 may contact the cable 250. The first temperature sensor 320 may measure the temperature of the cable 250.

The second temperature sensor 370 may measure the internal temperature of the body 310. According to embodiments, the second temperature sensor 370 may include a thermocouple temperature sensor, an RTD, an infrared temperature sensor, a thermistor, or the like. For example, the first temperature sensor 320 may contact the cable 250 or may be positioned at a first distance from the cable 250, and the second temperature sensor 370 may be positioned at a second distance from the cable 250. The second distance is greater than the first distance.

The controller 350 may control the temperature of the cable 250 based on the temperatures measured by the first temperature sensor 320 and the second temperature sensor 370. The cooler 400 may cool down the cable 250 inside the body 310. The fluid supply 450 may store the fluid to be supplied to the cooler 400. The fluid stored in the fluid supply 450 may include a fluid to be used in a FAB. The fluid supply 450 may supply the fluid to the cooler 400 through the fluid supply line 430. The fluid supply line 430 may be connected to each of the fluid supply 450 and the cooler 400. The valve 435 may adjust the flow rate of the fluid passing through the fluid supply line 430. The exhaust port 340 may be configured to discharge the fluid existing inside the body 310 to the outside of the body 310. The cable arrangement member 360 may be provided inside the body 310. The cable arrangement member 360 may be configured to fix the cable 250 inside the body 310. The temperature display panel 325 may be formed on the outer surface of the body 310. For example, the temperature display panel 325 may be formed on the outer surface of the body 310. The temperature display panel 325 may display at least any one of the temperatures measured by the first temperature sensor 320 and the second temperature sensor 370.

The overheat detection sensor 380 may be provided inside the body 310. The overheat detection sensor 380 may be configured to provide an alarm when the internal temperature of the body 310 is a set temperature T2 or higher. For example, the overheat detection sensor 380 may provide an alarm to a user through the temperature display panel 325 when the internal temperature of the body 310 is the set temperature T2 or higher. According to embodiments, the set temperature T2 may be higher by about 50% than the initial temperature TO of the cable 250. However, the set temperature T2 is not limited to the temperature range described above. The smoke detector 390 may be provided inside the body 310. When smoke is generated inside the body 310, the smoke detector 390 may measure the smoke.

While the inventive concept has been particularly shown and described with reference to embodiments thereof, it will be understood that various changes in form and details may be made therein without departing from the spirit and scope of the following claims.

What is claimed is:

1. A plasma processing apparatus comprising:
a chamber;
a lower electrode positioned inside the chamber and provided with first power, wherein a wafer is placed on an upper surface of the lower electrode;
a radio frequency (RF)-induced electrode positioned inside the chamber, wherein second power lower than the first power is induced to the RF-induced electrode;
an edge block impedance controller (EBIC) connected to the RF-induced electrode and configured to control an electric potential of the RF-induced electrode, wherein the EBIC is positioned outside the chamber;
a cable connected to the EBIC and positioned outside the chamber;
a lagging member surrounding the cable; and
a cooler configured to cool down the cable.

2. The plasma processing apparatus of claim 1,
wherein the lagging member comprises:
a body having an inner space in which the cable is positioned; and
a first temperature sensor configured to measure a temperature of the cable in the inner space of the body.

3. The plasma processing apparatus of claim 2, further comprising:
a second temperature sensor configured to measure an internal temperature of the inner space of the body,
wherein a first distance between the first temperature sensor and the cable in the inner space of the body is shorter than a second distance between the second temperature sensor and the cable in the inner space of the body.

4. The plasma processing apparatus of claim 2, further comprising:
a fluid supply configured to store a fluid;
a fluid supply line connecting the fluid supply to the cooler; and
a valve configured to adjust a flow rate of the fluid passing through the fluid supply line.

5. The plasma processing apparatus of claim 4, further comprising:
a controller configured to control opening and closing of the valve based on the temperature of the cable, which is measured by the first temperature sensor.

6. The plasma processing apparatus of claim 5,
wherein the controller is further configured to open the valve when the temperature of the cable, which is measured by the first temperature sensor, reaches or exceeds a first set temperature, and
wherein the first set temperature is higher by about 10% to about 20% than an initial temperature of the cable.

7. The plasma processing apparatus of claim 2,
wherein the body of the lagging member comprises fabric.

8. The plasma processing apparatus of claim 1,
wherein a length of the lagging member in a first horizontal direction has a value in a range of about 36 cm to about 44 cm,
wherein a length of the lagging member in a vertical direction has a value in a range of about 72 cm to about 88 cm, and
wherein a length of the lagging member in a second horizontal direction has a value in a range of about 2.7 cm to about 3.3 cm.

9. The plasma processing apparatus of claim 1,
wherein a length of the cable has a value in a range of about 2.9 m to about 3.1 m.

10. The plasma processing apparatus of claim 1, further comprising:
an overheat detection sensor configured to trigger an alarm when an internal temperature of the lagging member reaches or exceed a second set temperature.

11. The plasma processing apparatus of claim 1, further comprising:
a cable arrangement member around which the cable inside the inner space of the body of the lagging member is wound.

12. The plasma processing apparatus of claim 1, further comprising:
an insulating plate positioned inside the chamber and surrounding a side wall of the lower electrode;
a focus ring on the insulating plate, wherein the RF-induced electrode has a ring shape and is buried in the insulating plate;
an RF output rod, which is connected to the RF-induced electrode and outputs third power that is lower than the second power to the outside of the chamber; and
an RF-induced rod connecting the RF-induced electrode to the RF output rod and penetrating the insulating plate.

13. A plasma processing apparatus comprising:
a chamber configured to perform plasma etching on a wafer;
an edge block impedance controller (EBIC) outside the chamber;
a cable connected to the EBIC and positioned outside the chamber;
a body having an inner space in which the cable is positioned;
a first temperature sensor configured to measure a temperature of the cable in the inner space of the body;
a cooler configured to cool down the cable;
a fluid supply configured to store a fluid to be provided to the cooler;
a fluid supply line connecting the cooler to the fluid supply;
a valve configured to adjust a flow rate of the fluid passing through the fluid supply line;
a controller configured to control opening and closing of the valve based on the temperature of the cable, which is measured by the first temperature sensor;
a lower electrode positioned inside the chamber and provided with first power; and
a radio frequency (RF)-induced electrode having a ring shape and connected to the EBIC, wherein second power that is lower than the first power is induced to the RF-induced electrode.

14. The plasma processing apparatus of claim 13,
wherein the controller is further configured to open the valve when the temperature of the cable, which is measured by the first temperature sensor, reaches or exceed a first set temperature, and
wherein the first set temperature is higher by about 10% to about 20% than an initial temperature of the cable.

15. The plasma processing apparatus of claim 13, further comprising:
an overheat detection sensor configured to trigger an alarm when an internal temperature of the inner spacer of the body reaches or exceeds a second set temperature,
wherein the second set temperature is higher by about 50% than an initial temperature of the cable.

16. The plasma processing apparatus of claim 13, further comprising:
a cable arrangement member around which the cable inside the inner space of the body is wounded,
wherein a groove is formed at an outer surface of the cable arrangement member to secure the cable.

17. The plasma processing apparatus of claim 13, further comprising:
a second temperature sensor configured to measure an internal temperature of the inner space of the body; and
an exhaust port configured to discharge the fluid in the inner space of the body to an outside of the body.

18. A plasma processing apparatus comprising:
a chamber configured to perform plasma etching on a wafer;
an edge block impedance controller (EBIC) outside the chamber;
a cable connected to the EBIC and positioned outside the chamber;
a body having an inner space in which the cable is positioned;
a first temperature sensor configured to measure a temperature of the cable;
a cooler configured to cool down the cable;
a fluid supply configured to store a fluid to be provided to the cooler;
a fluid supply line connecting the cooler to the fluid supply;
a valve configured to adjust a flow rate of the fluid passing through the fluid supply line;
a controller configured to control opening and closing of the valve based on the temperature of the cable, which is measured by the first temperature sensor;
a lower electrode positioned inside the chamber and provided with first power;
an insulating plate surrounding a side wall of the lower electrode;
a focus ring on the insulating plate;
a radio frequency (RF)-induced electrode having a ring shape and buried in the insulating plate, wherein second power that is lower than the first power is induced to the RF-induced electrode;
an RF output rod, which is connected to the RF-induced electrode and outputs third power that is lower than the second power to the outside of the chamber; and
an RF-induced rod connecting the RF-induced electrode to the RF output rod and penetrating the insulating plate,
wherein the controller is further configured to open the valve when the temperature of the cable, which is measured by the first temperature sensor, reaches or exceeds a first set temperature, and
wherein the first set temperature is higher by about 10% to about 20% than an initial temperature of the cable.

19. The plasma processing apparatus of claim 18,
wherein a length of the cable is a value in a range of about 2.9 m to about 3.1 m,
wherein a length of the body in a first horizontal direction is a value in a range of about 36 cm to about 44 cm,
wherein a length of the body in a vertical direction is a value in a range of about 72 cm to about 88 cm, and
wherein a length of the body in a second horizontal direction is a value in a range of about 2.7 cm to about 3.3 cm.

20. The plasma processing apparatus of claim 18, further comprising:
a cable arrangement member around which the cable inside the inner space of the body is wounded.
